(19) United States
(12) Patent Application Publication
(10) Pub. No.: US 2007/0020956 A1
(43) Pub. Date: Jan. 25, 2007

(54) Semiconductor device and method for manufacturing the same

(76) Inventors: Yoshiki Kamata, Tokyo (JP); Akira Nishiyama, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/486,252

(22) Filed: Jul. 14, 2006

(30) Foreign Application Priority Data
Jul. 19, 2005 (JP) 2005-208967

(51) Int. Cl. H01L 21/31

(52) U.S. Cl. 438/782

(57) ABSTRACT

It is made possible to reduce the influence upon adjacent elements. Voids are provided in a Ge substrate. An insulation film containing Ge is provided to cover top faces of the voids.

### CROSS-REFERENCE TO RELATED APPLICATION

This application is based upon and claims the benefit of priority from prior Japanese Patent Application No. 2005-208967 filed on Jul, 19, 2005 in Japan, the entire contents of which are incorporated herein by reference.

### BACKGROUND OF THE INVENTION

1. Field of the Invention

The present invention relates to a semiconductor device which has a void formed in a semiconductor substrate, and its manufacturing method.

2. Related Art

Conventionally, a method for forming an element isolation region formed of an insulator to electrically isolate elements formed on a semiconductor substrate from each other is used. The LOCOS (local oxidation of silicon) method of oxidizing only a desired portion by using a suitable mask to conduct element isolation and the STI (shallow trench isolation) method of providing a trench on a substrate and burying an insulation substance in the trench to conduct element isolation are known. With the advance of higher element integration, the element isolation method is shifting from the LOCOS method to the STI method which makes possible higher integration. In the STI method, however, it is necessary to conduct planarization processing for making the element isolation region formed of an insulation substance buried in the trench nearly parallel to the semiconductor substrate by using CMP (chemical mechanical polishing) equipment. This results in a problem that the cost of the expensive CMP equipment is added to the cost of elements and the manufacturing cost becomes high.

If the purpose is only to electrically separate elements from each other, it can be attained by simply forming a trench between elements and making the physical length of the elements on the semiconductor substrate. In this case, however, the trench is unintentionally filled with an electrode material in a later process, for example, in an electrode forming process, and consequently the element isolation characteristics are degraded as compared with the case where an insulation substance is buried in the trench. In order to avoid this, a conventional art of forming a trench, then oxidizing the bottom face and side faces of the trench, subsequently causing an epitaxial layer to grow over the whole face of the semiconductor substrate to cover the top surface of the trench, and then oxidizing only the epitaxial layer portion which covers the trench is known (see, for example, JP-A 10-233440 (KOKAI)). However, the conventional art described in the JP-A 10-233440 has a problem that the number of processes required to form the element isolation region is large.

Furthermore, in recent years, propagation delay caused by wiring (hereafter referred to as wiring delay) has posed a problem. The attempt to lower the permittivity of an insulation substance (hereafter referred to as interlayer insulation film) is being continued. Ultimately, however, it is desired that the interlayer insulation film has a relative permittivity of unity, i.e., there is air, i.e., a void between wiring pieces. Therefore, a structure of the interlayer having holes in a porous form is also proposed. In this case, however, there are a problem that holes are filled with the electrode material and the like in a later process and a problem that the strength of the interlayer insulation film itself is weak.

In recent years, an element utilizing a silicon layer on a void by using the surface diffusion phenomenon is reported and remarked (see, for example, Tsunashima, Y.; Sato, T.; Mizushima, I., “A new substrate engineering technique to realize silicon on nothing (SON) structure utilizing transformation of sub-micron trenches to empty space in silicon (ESS) by surface migration,” High Purity Silicon VI. Proceedings of the Sixth International Symposium (Electromechanical Society Proceedings Vol. 2000-17) (SPIE Vol. 4218), pp. 532-45 (2000)). This is called SON (silicon on nothing). Since a buried oxide film (hereafter also referred to as BOX (buried oxide)) has a permittivity of 1, it is considered to be an ultimate SOI structure. However, it is necessary to let reducing gas such as hydrogen flow in a high vacuum at the time of manufacturing, resulting in complexity in the process. As for the fabrication method of SON, a method of utilizing damage caused at the time of CDE (chemical dry etching) (see, for example, Usuda K, Numata T, Tezuka T, Sugiyama N, Moriyama Y, Nakaharai S and Takagi S, 2003 Strain evaluation for thin strained-Si on SGOI and strained-Si on nothing (SSON) structures using nano-beam electron diffraction (NBD) Proc. IEEE Int. SOI Conf., pp. 138-9) and an example of selective etching a SiGw layer which lies under a Si layer by using an isotropic plasma process is also reported (see, for example, Jurczak, M.; Skotnicki, T.; Paoli, M.; Tormen, B.; Regolini, J.-L.; Morin, C.; Schiliz, A.; Martins, J.; Pantel, R.; Galvier, J., “SON (silicon on nothing)—a new device architecture for the ULSI era,” 1999 Symposium on VLSI Technology, Digest of Technical Papers, pp. 29-30 (1999)). Furthermore, SOI has a problem that heat generated at the time of operation of elements does not flow out easily as compared with a bulk silicon substrate because a BOX layer which is inferior to silicon in thermal conductivity is present on the substrate side of a current drive element.

As for a detector on the semiconductor substrate, a structure having no substance around the detector is adopted in the same way as the wiring, in some cases. Especially, in the case of an infrared detector, it is not desirable that heat does flow out from the detector, and consequently a structure having a coil-like detector floated in the air is used. In this case, however, the detector is bent by its weight, and consequently the arrangement and size of elements are limited.

As for a method for reducing the silicon oxide, it can be conducted by applying heat if metal that is low than the silicon oxide in Gibbs free energy and that forms a stable oxide can be brought into direct contact with the silicon substrate. In recent years, it is reported that it is possible to form a film of titanium on a high permittivity film and reduce an interface layer formed in an interface between a silicon substrate and the high permittivity film (see, for example, Hyoungsub Kim, Paul C. McIntyre, Chi On Chui, Krishna C. Saraswat, and Susanne Stemmer, “Engineering chemically abrupt high-k metal oxide/silicon interfaces using an oxygen-gettering metal overlayer,” J. Appl. Phys. 96, 3467 (2004)).

In recent years, development of a high permittivity film having a higher permittivity than SiO₂ has been promoted as a gate insulation film replacing SiO₂. Furthermore, it is started to study a Ge substrate again as a semiconductor substrate replacing a Si substrate. It is known that a high permittivity film formed on a Ge substrate has a Ge oxide as an interface layer and Ge is diffused into the high permittivity film by conducting heat treatment. Furthermore, it is known that a high permittivity film containing Ge has a permittivity between a permittivity of the high permittivity film simple substance and a permittivity of the Ge oxide simple substance (see, for example, JP-A 2005-191293 (KOKAI)).

### SUMMARY OF THE INVENTION

A semiconductor device according to a first aspect of the present invention includes: a Ge substrate having a void; and an insulation film containing Ge which covers a top face of the void.

A semiconductor device according to a second aspect of the present invention includes: a semiconductor substrate having a void; an insulation film which covers a top face of the void; and wiring provided on the insulation film above the void.

A semiconductor device according to a third aspect of the present invention includes: a semiconductor substrate having a void; an insulation film which covers a top face of the void; and an infrared detector provided on the insulation film above the void.

A semiconductor device according to a fourth aspect of the present invention includes: a semiconductor substrate having a void, a top face of the void being covered by an insulation film, wherein the void is filled with a coolant for cooling the semiconductor substrate or the coolant passes through the void.

A semiconductor device manufacturing method according to a fifth aspect of the present invention includes: forming an insulation film on a Ge substrate; and forming a void in the Ge substrate under the insulation film.

A semiconductor device manufacturing method according to a sixth aspect of the present invention includes: etching a surface of a semiconductor substrate, and forming a first void, a second void which is connected to the first void and which is narrower in width than the first void, and a third void connected to the second void; burying a first insulation film in the first to third voids; forming a second insulation film which is lower in etching rate than the first insulation film so as to cover a face of the semiconductor substrate in which the first to third voids are formed; forming an opening which leads to the first insulation film buried in the third void by etching and removing at least a part of the second insulation film on the third void; and removing the first insulation film buried in the first to third voids by conducting etching via the opening.

A semiconductor device manufacturing method according to a seventh aspect of the present invention includes: forming an insulation film on a surface of an SOI substrate; etching the insulation film and an SOI layer of the SOI substrate and thereby forming an opening leading to a buried oxide film of the SOI substrate; and etching and removing a partial region of the buried oxide film via the opening and thereby forming a void.

### BRIEF DESCRIPTION OF THE DRAWINGS

FIG. 1 is a sectional view showing a semiconductor device according to a first embodiment of the present invention;

FIG. 2 is a photograph of a TEM for explaining a manufacturing principle of a void according to the first embodiment;

FIG. 3 is a sectional view showing a semiconductor device according to a second embodiment of the present invention;

FIG. 4 is a plan view of a semiconductor device according to a third embodiment of the present invention;

FIG. 5 is a sectional view taken along a line A-A shown in FIG. 4;

FIG. 6 is a sectional view showing a semiconductor device according to a fourth embodiment of the present invention;

FIG. 7 is a plan view showing a manufacturing process of a semiconductor device according to a second example of the present invention;

FIG. 8 is a sectional view taken along a line A-A shown in FIG. 7;

FIG. 9 is a sectional view taken along a line B-B shown in FIG. 7 in its manufacturing process;

FIG. 10 is a sectional view taken along a line C-C shown in FIG. 7;

FIG. 11 is a plan view showing a manufacturing process of a semiconductor device according to a second example;

FIG. 12 is a sectional view taken along a line A-A shown in FIG. 11;

FIG. 13 is a sectional view showing a manufacturing process of a semiconductor device according to a second example;

FIG. 14 is a plan view showing a manufacturing process of a semiconductor device according to the second example;

FIG. 15 is a sectional view taken along a line A-A shown in FIG. 14;

FIG. 16 is a sectional view taken along a line B-B shown in FIG. 14;

FIG. 17 is a sectional view taken along a line C-C shown in FIG. 14;

FIG. 18 is a sectional view taken along a line B-B shown in FIG. 14 in a state in which epitaxial growth is caused in a void and a necking area is not blocked;

FIG. 19 is a sectional view taken along a line C-C shown in FIG. 14 in a state in which epitaxial growth is caused in a void and a necking area is not blocked;

FIG. 20 is a sectional view taken along a line B-B shown in FIG. 14 in a state in which epitaxial growth is caused in a void and a necking area is blocked;

FIG. 21 is a sectional view taken along a line C-C shown in FIG. 14 in a state in which epitaxial growth is caused in a void and a necking area is blocked;

FIG. 22 is a diagram showing dependence of degassing of GeO(g) upon temperature in an HfO₂/GeO₂ stacked structure;

FIG. 23 is a plan view showing a manufacturing process of a semiconductor device according to a ninth example of the present invention;

FIG. 24 is a sectional view taken along a line A-A shown in FIG. 23;

FIG. 25 is a sectional view showing a manufacturing process of a semiconductor device according to a ninth example of the present invention;

FIG. 26 is a sectional view showing a manufacturing process of a semiconductor device according to a ninth example of the present invention;

FIG. 27 is a plan view showing a manufacturing method according to a twelfth example;

FIG. 28A is a sectional view taken along a line A-A shown in FIG. 27, and FIG. 28B is a sectional view taken along a line B-B shown in FIG. 27;

FIG. 29 is a plan view showing a manufacturing method according to a twelfth example;

FIG. 30A is a sectional view taken along a line A-A shown in FIG. 29, and FIG. 30B is a sectional view taken along a line B-B shown in FIG. 29;

FIG. 31 is a plan view showing a manufacturing method according to a twelfth example;

FIG. 32A is a sectional view taken along a line A-A shown in FIG. 31, and FIG. 32B is a sectional view taken along a cutting line B-B shown in FIG. 31;

FIG. 33A is a sectional photograph obtained by using an SEM (scanning electron microscope) after conducting heat treatment on a sample having a Mo film containing oxygen formed on a ZrO₂ film, in an atmosphere of nitrogen at 600° C. for 30 minutes;

FIG. 33B is a sectional photograph obtained by using an SEM after conducting heat treatment on a sample having a Mo film containing oxygen formed on a ZrO₂ film, in an atmosphere of nitrogen at 700° C. for 30 minutes;

FIG. 34A is a sectional photograph obtained by using an SEM after conducting heat treatment on a sample having no Mo film containing oxygen formed on a ZrO₂ film, in an atmosphere of nitrogen at 600° C. for 30 minutes;

FIG. 34B is a sectional photograph obtained by using an SEM after conducting heat treatment on a sample having no Mo film containing oxygen formed on a ZrO₂ film, in an atmosphere of nitrogen at 700° C. for 30 minutes;

FIG. 35 is a diagram showing an SIMS analysis result of oxygen intensity of a sample having a Mo film containing oxygen formed on a ZrO₂ film; and

FIG. 36 is a diagram showing an SIMS analysis result of germanium intensity of a sample having a Mo film containing oxygen formed on a ZrO₂ film.

### DETAILED DESCRIPTION OF THE INVENTION

Hereafter, embodiments of the present invention will be described with reference to the drawings.

### First Embodiment

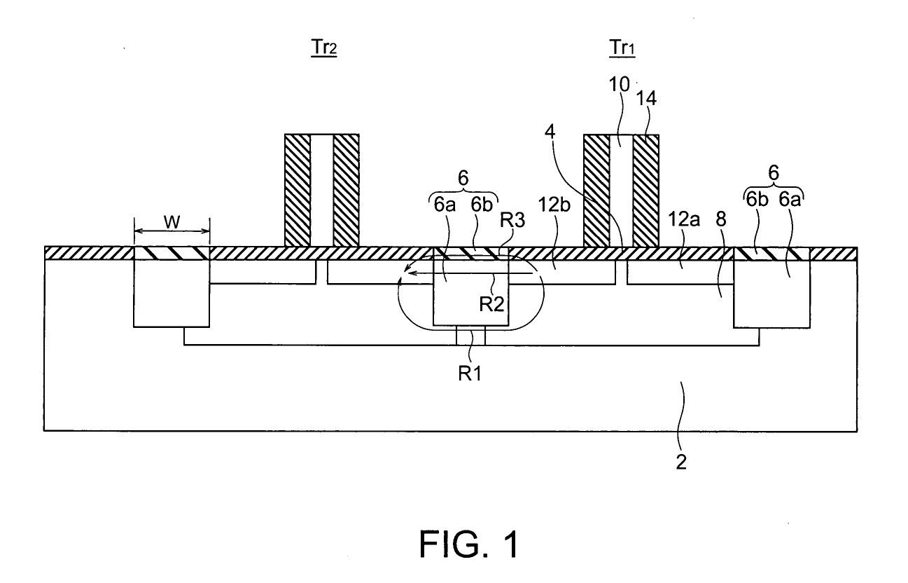

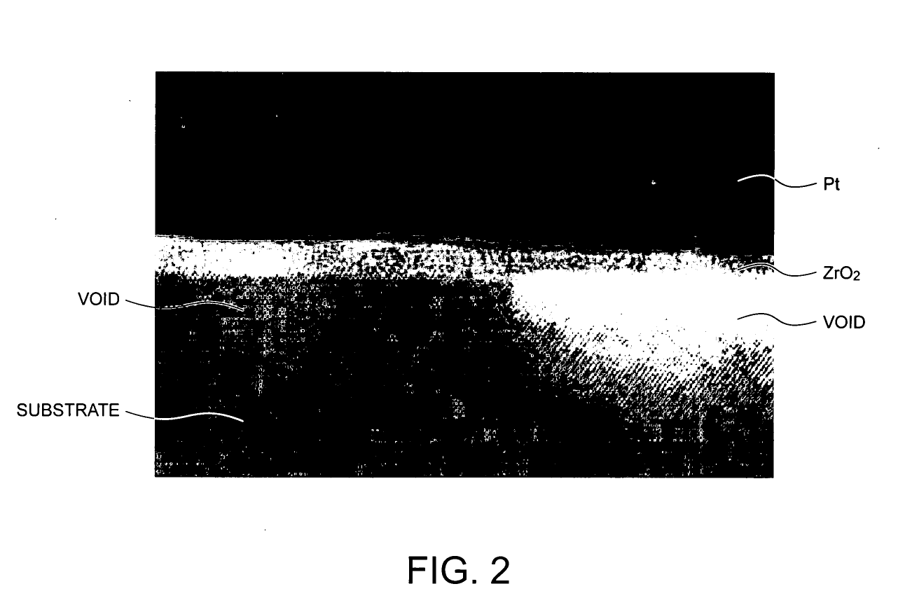

A semiconductor device according to a first embodiment of the present invention will now be described with reference to FIGS. 1 and 2. The semiconductor device according to the present embodiment includes a plurality of elements (such as field effect transistors (hereafter also referred to as FETs)) formed on a Ge substrate, and has a configuration using a void for element isolation of these elements.

The void is formed on the following knowledge of the present inventors. The present inventors have vigorously studied forming of a high-k film on the Ge substrate. As a result, the present inventors have obtained the following knowledge.

First, when a Ge substrate having no film formed on the surface is subjected to heat treatment, holes are proved to be formed on the Ge substrate according to crystallinity of Ge. According to a plurality of experiment results, as the partial pressure of oxygen in gas becomes lower and the heat treatment becomes high in temperature, holes tend to be opened. From the knowledge that three conditions of Si, SiO₂ and vacuum are necessary in the decomposition of SiO₂ on a Si substrate into SiO, the above-described experimental fact suggests that similar conditions are necessary in the Ge substrate as well.

Furthermore, the higher etch pit density (hereafter also referred to as EPD) of the Ge substrate has, the larger the number of opened holes becomes significantly. Therefore, it is expected that places where holes are opened reflect crystal defects which are present near the surface of the Ge substrate.

On the contrary, if heat treatment is conducted at 500° C. in an atmosphere having a high oxygen partial pressure, such as an atmosphere of oxygen, then the surface of the Ge substrate is oxidized, and degassing of a Ge oxide is caused. As a result, the whole surface is etched, resulting in increased surface roughness. This can be appreciated from the knowledge that GeO₂ is easily decomposed into GeO unlike SiO₂.

It is expected from the foregoing description that there is a trade-off relation between the oxygen partial pressure in gas and the roughness of the Ge substrate surface and the surface roughness is minimized at a certain oxygen partial pressure.

If an insulation film formed of ZrO₂ is formed on the surface of the Ge substrate, then a metal film formed of platinum (Pt) is subjected to electron beam evaporation (hereafter referred to as EB evaporation), and then heat treatment (for example, annealing at 600° C. in an atmosphere of nitrogen for 30 minutes), then voids are formed in a Ge substrate region which is a part under the ZrO₂ film. This fact is proved to be true from an electron beam transmission measurement image measured using a transmission electron microscope (hereafter referred to as TEM) (see FIG. 2). Since the contrast of ZrO₂ remains approximately the same regardless of whether there are voids, the film thickness of the electron beam transmission measurement image of the TEM in the depth direction is proved to be in approximately the same order and the contrast difference of the Ge substrate is proved to be caused by whether there are voids. Although ZrO₂ over voids contains much Ge, Zr and Ge are close in atomic number and similar in the so-called Z contrast. Therefore, the contrast of the TEM image looks unchanged regardless of whether there are voids.

The place where the voids are formed is considered to be a defect place which is originally in the Ge substrate, or a place damaged at the time of the surface processing of the Ge substrate, at the time of forming an insulation film formed of ZrO₂, or at the time of EB evaporation. As far as the present inventors know, there is heretofore no example of implementation of a structure in which a void region lies under an insulation film and the insulation film is bridged over the semiconductor substrate.

Furthermore, in a different experiment, it is found from X-ray photoelectric spectrophotometry (hereafter referred to as XPS measurement) that Ge is contained in the ZrO₂ film if a ZrO₂ film is formed on the Ge substrate and then heat treatment is conducted. The bonding form of Ge in the ZrO₂ film is an oxide.

In addition, therefore, a permittivity of an MGeO film is estimated from capacitance measurement by conducting an experiment while changing the quantity of GeO₂ added to a high permittivity film having a permittivity of approximately 20 made of ZrO₂ or HfO₂. Here, M represents Zr or Hf. The MGeO film has a permittivity lying between the permittivity of MO₂ and that of GeO₂. The reference value of the permittivity (κGeO₂) of GeO₂ is approximately 7 although it varies somewhat. A permittivity value of GeO₂ obtained by extrapolating a graph obtained from results of the experiment also has a value close to 7. The larger the GeO2 content gets, the smaller the permittivity becomes. In other words, the permittivity of the high-k film is proved to decrease as the Ge content increases.

A semiconductor device according to a first embodiment of the present invention is shown in FIG. 1. The semiconductor device according to the present embodiment includes a plurality of field effect transistors Tr1 and Tr2 provided on a Ge substrate 2. Each transistor Tri (i=1, 2) is provided on a well region 8 formed on a Ge substrate 2. Each transistor Tri includes a gate insulation film formed on the well region 8, a gate electrode 10 provided on the gate insulation film 4, a source region 12a and a drain region 12b provided in the well region 8 on both sides of the gate electrode 10, and a gate side wall 14 made of an insulator and provided around the side of the gate electrode 10. By the way, in the present embodiment, the gate insulation film is formed of a high permittivity substance.

These transistors Tr1 and Tr2 are element-isolated by element isolation regions 6. Each of the element isolation regions 6 includes a void 6a provided in the Ge substrate 2, and an insulation film 6b formed of Ge so as to cover the top surface of the void 6a. The top surface of the insulation film 6b and the top surface of the gate insulation film 6 are substantially coplanar.

A manufacturing method of the semiconductor device according to the present embodiment will now be described. First, element isolation regions 6 are formed in the Ge substrate 2. Formation of the element isolation regions 6 is conducted as described below.

First, crystal defects are formed in an area where the element isolation region is to be formed in the Ge substrate 2. Formation of the crystal defects is conducted by using, for example, ion implantation. Subsequently, an insulation film of a high permittivity substance is formed over the whole surface of the Ge substrate 2. An insulation film of the high permittivity substance formed in an area where crystal defects are not formed becomes the gate insulation film 4. Thereafter, annealing is conducted in an atmosphere of inert gas or nitrogen gas. As described above, the voids 6a are formed in regions where crystal defects are formed. In addition, Ge is diffused from the area where crystal defects are formed into the insulation film on the area where crystal defects are formed. Therefore, germanium is contained in the insulation film 6b which covers the top surface of the void 6a. The same component as the high permittivity substance of the gate insulation film 4 is contained in the insulation film 6b besides Ge. By the way, formation of crystal defects may be conducted after an insulation film of a high permittivity substance is formed over the whole surface of the Ge substrate 2. Subsequent transistor formation is conducted by using the well-known technique.

In the semiconductor device according to the present embodiment, a potential at the drain 12b of the transistor Tr1 differs depending upon the condition of a potential applied to the gate electrode 10 of the transistor Tr1. It is a role of the element isolation region 6 to prevent the potential at the drain 12b from affecting the adjacent element (the transistor Tr2). Typically, the element isolation region 6 including the void 6a having a long geometrical route is designed so as to make a voltage drop along a route R1 shown in FIG. 1 sufficient. A width W of the element isolation region 6 is restricted by a resolution of an exposure equipment. If this width W is small, however, parasitic capacitor through the element isolation region 6 becomes large and the potential state of the drain 12b of the transistor Tr1 affects the adjacent transistor Tr2 via a route R2.

In the present embodiment, it is possible to make the geometric route long and reduce the influence over the adjacent element via the route R1 as far as possible by suitably setting the width W of the element isolation region 6, i.e., the width of the crystal defect region.

Furthermore, the element isolation region 6 includes the void 6a, and the permittivity of the void 6 is as low as approximately 1. As a result, the influence over the adjacent element via the route R2 can be reduced.

If a gate insulation film of a high permittivity substance is deposited after the element isolation region is formed by using the STI method as in the conventional art, then the insulation film of the high permittivity substance is unadvantageously formed on the element isolation region as well. For example, the void 6a shown in FIG. 1 is first formed and the void 6a is filled with a silicon oxide. Thereafter, the insulation film formed of the high permittivity substance is deposited. If the insulation film of the high permittivity substance is thus present on the element isolation region, then the following problem is caused unlike the conventional case where elements are isolated by only a low permittivity substance containing Si, such as SiO₂. The problem is that the ratio of lines of electric force which emanate from the transistor Tr1, pass through the high-k film along a route R3 shown in FIG. 1, and terminate in the adjacent element (the transistor Tr2) increases and various influences are exerted upon the adjacent element.

In the present embodiment, however, Ge diffused from the Ge substrate 2 taking a form of a germanium oxide is contained in the insulation film 6b which covers the top surface of the void 6a. Therefore, the insulation film 6b becomes lower in permittivity than the gate insulation film 4, and the ratio of the lines of electric force which emanate from the transistor Tr1, pass through along the route R3, and terminate in the adjacent transistor Tr2 becomes small. As a result, the influence of the route R3 can be reduced as far as possible.

According to the present embodiment, it is possible to obtain a semiconductor device including an element isolation region capable of reducing the influence upon the adjacent element as far as possible as heretofore described.

The number of processes for fabrication of the element isolation region according to the present embodiment is three: formation of the crystal defect region, formation of the high-k film, and heat treatment. On the other hand, the technique described in Japanese Patent Application Laid-open No. 10-233440 needs at least four processes: trench formation, oxidation of trench side and bottom faces, epitaxial layer formation on a semiconductor substrate, and epitaxial layer oxidation on the trench. Therefore, the number of manufacturing processes for the semiconductor device according to the present embodiment can be made smaller than that described in JP-A 10-233440 (KOKAI).

### Second Embodiment

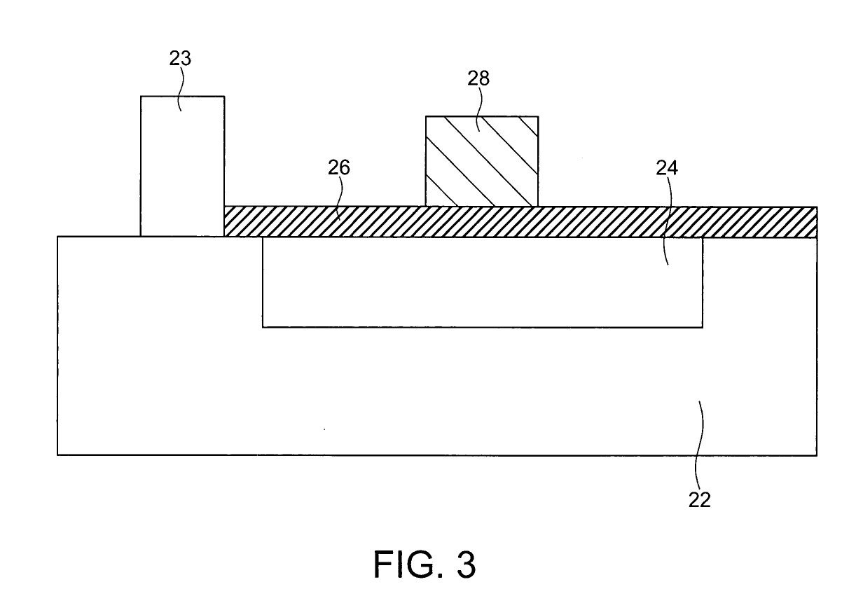

A semiconductor device according to a second embodiment of the present invention is shown in FIG. 3. In the semiconductor device according to this embodiment, wiring 28 adjacent to an element (for example, a field effect transistor) 23 provided on a semiconductor substrate 22 is formed on an insulation film 26 formed to cover a void 24, so as to pass over the void 24 provided in a region of the semiconductor substrate 22 located near the element 23. In other words, the wiring 28 is formed so as to locate a part of the wiring 28 over the void 24.

Conventionally, when the wiring 28 is disposed over the semiconductor substrate 22, the wiring/ insulation film/ substrate functions as a parasitic MIS capacitor. It is typically necessary to make the insulation film 26 located under the wiring 28 sufficiently thick in order to prevent faulty operation of the adjacent element 23.

In the present embodiment, however, false operation can be prevented as compared with the case where the entire inside of the void 24 is filled with the insulation film, because the void 24 having a permittivity which is as small as approximately 1 is interposed between the wiring 28 and the substrate 22.

### Third Embodiment

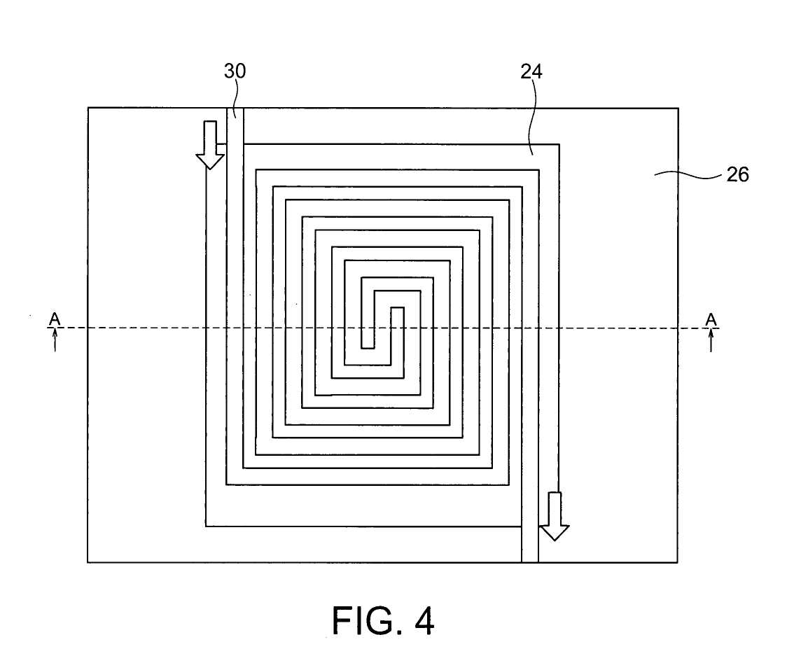

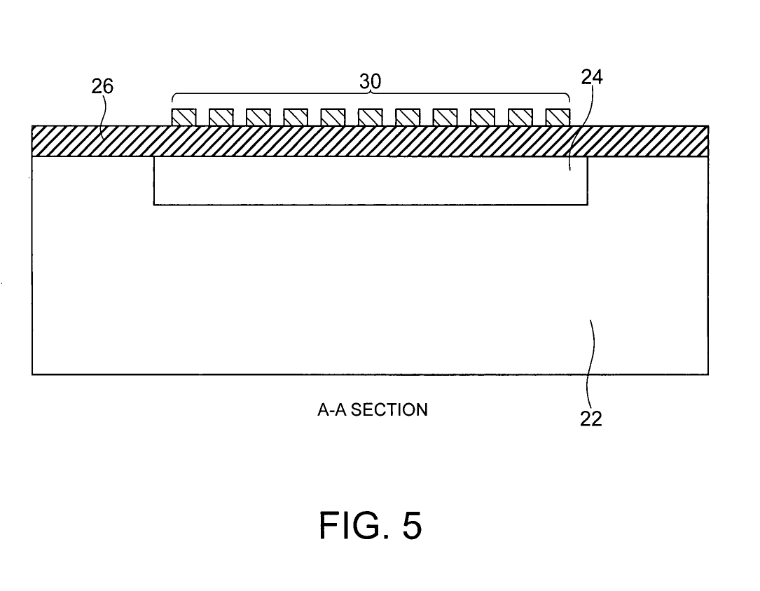

A semiconductor device according to a third embodiment of the present invention will now be described with reference to FIGS. 4 and 5. FIG. 4 is a plan view of the semiconductor device according to the present embodiment. FIG. 5 is a sectional view obtained when the semiconductor device is cut along a cutting line A-A shown in FIG. 4. The semiconductor device according to the present embodiment includes a detector (for example, an infrared detector) 30. This detector 30 is provided over the void 24 formed in the semiconductor substrate 22 via the insulation film 26 so as to take the shape of a coil.

In the conventional infrared detector, a structure having a coil-shaped infrared detector floated in the air is used to prevent heat from staying in the infrared detector itself. In this case, the infrared detector is bent by its weight, and consequently the disposition and size of the detector is restricted.

Since the detector 30 is provided over the void 24 via the insulation film 26 in the present embodiment, however, the detector can be designed freely without restrictions unlike the conventional case.

Furthermore, in the case where the void 24 is formed as in the present embodiment as compared with the case where the inside of the void 24 is filled with an insulator, the influence of the potential at the detector 30 upon the semiconductor substrate 22 can be decreased and false operation can be remarkably reduced.

### Fourth Embodiment

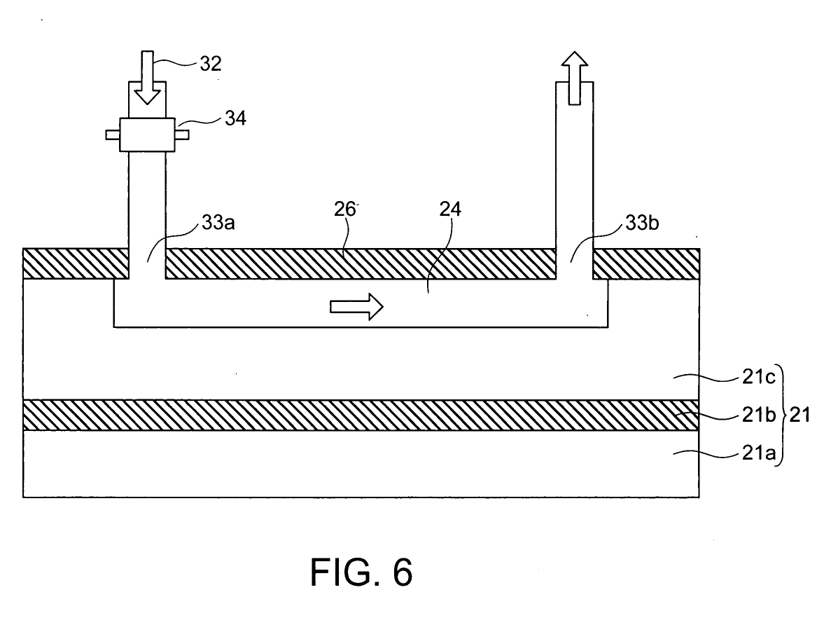

A semiconductor device according to a fourth embodiment of the present invention is shown in FIG. 6. The semiconductor device according to the present embodiment has a configuration in which a void 24 is provided in an SOI layer 21c of the SOI substrate 21 including a supporting substrate 21a, a buried oxide layer 21b, and the SOI layer 21c, an insulation film 26 is provided so as to cover the void 24, and the void 24 is filled with a coolant 32. The coolant 32 is fed into the void 24 via a coolant intake 33a provided at one end of the void 24 by a coolant circulator 34, exhausted from an outlet 33b provided at the other end of the void 24, and returned to the coolant circulator 34.

Since a large number of semiconductor elements generate heat at the time of operation and the generated heat degrades element characteristics, heat radiation mechanisms of the elements are important. As a general heat radiation mechanism, a fan is attached to the surface of each element to conduct air cooling, or a fin having a high thermal conductivity and a large surface area is stuck on each element via grease or the like with close adhesion.

On the other hand, since the coolant is in direct contact with the semiconductor substrate of the heat generation source in the present embodiment, the heat radiation efficiency is good. If the thermal conductivity of the coolant is high and the volume ratio of the element to the coolant is large, then it is effective to merely fill the void 24 of the substrate 21 with the coolant. Since the coolant circulator 34 is also provided in order to enhance the convection of the coolant in the present embodiment, it is more effective.

By the way, a micro-machine developed in recent years can be used as the coolant circulator 34. For example, it is possible to convect the coolant only in one direction by forming a valve on the convection route of the coolant and applying vibration to the coolant.

According to the present embodiment, it is possible to reduce the influence of heat upon not only the element itself which generates heat but also the element adjacent to the element which generates heat, as heretofore described.

Hereafter, the embodiments of the present invention will be described in further detail with reference to examples.

### FIRST EXAMPLE

A semiconductor device according to a first example of the present invention will now be described. In the semiconductor device according to the present example, an insulation film, for example, a ZrO₂ film is formed on the surface of a Ge single crystal substrate by conducting sputtering of approximately 3 nm, and then heat treatment is conducted. As a result, a void is formed in the Ge substrate under the ZrO₂ film in the same way as the description of the first embodiment. And this void is used as the element isolation region, and other regions in the Ge substrate are used as the element region. A semiconductor element is formed in the element region.

As a method for crystal defects in the Ge substrate in order to form the void, ion implantation or chemical dry etching may be used. As for the order of the crystal defect formation, it may be either of before and after the formation of the insulation film.

### SECOND EXAMPLE

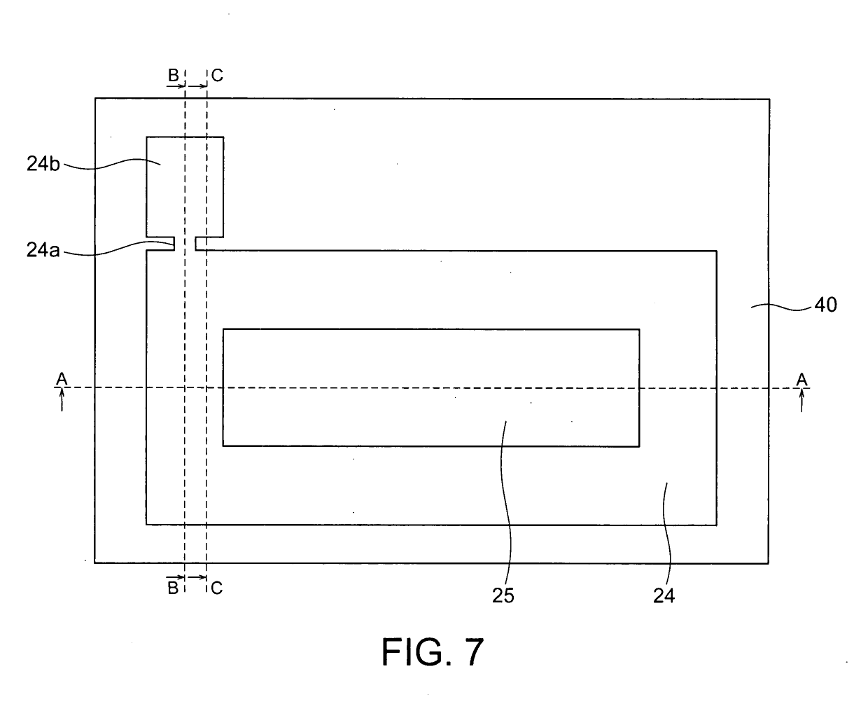

A semiconductor device according to a second example of the present invention will now be described with reference to FIGS. 7 to 21. In the semiconductor device according to the present example, a region 25 surrounded by a void 24 formed in a semiconductor substrate 22 is used as the element region, the void 24 is used as the element isolation region, and the top surface of the void is covered by an insulation film. This semiconductor device is formed as hereafter described.

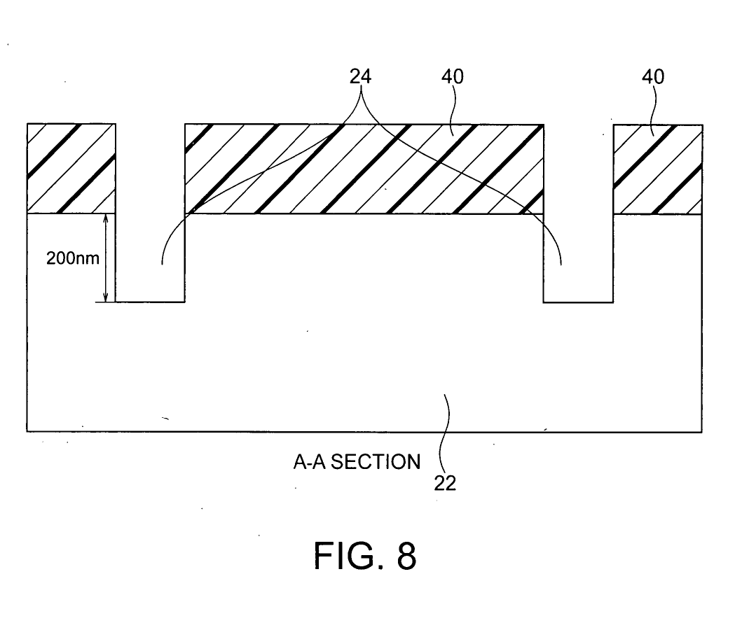

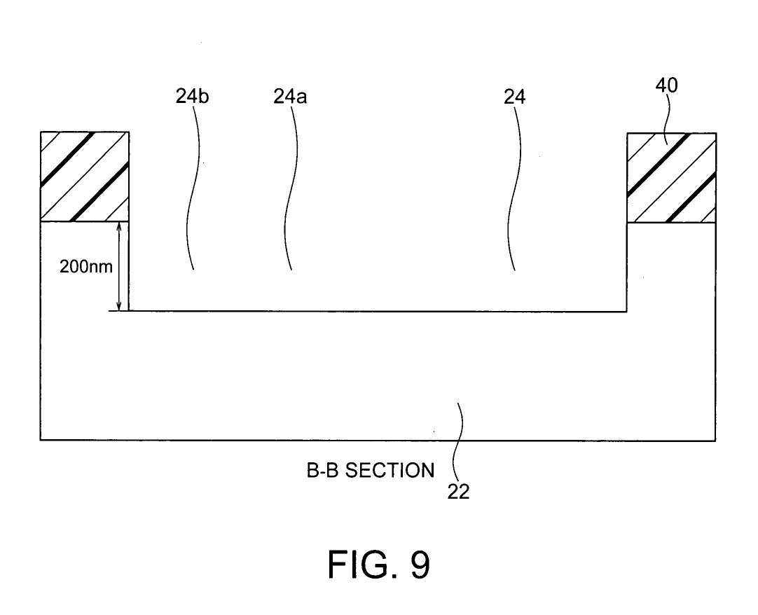

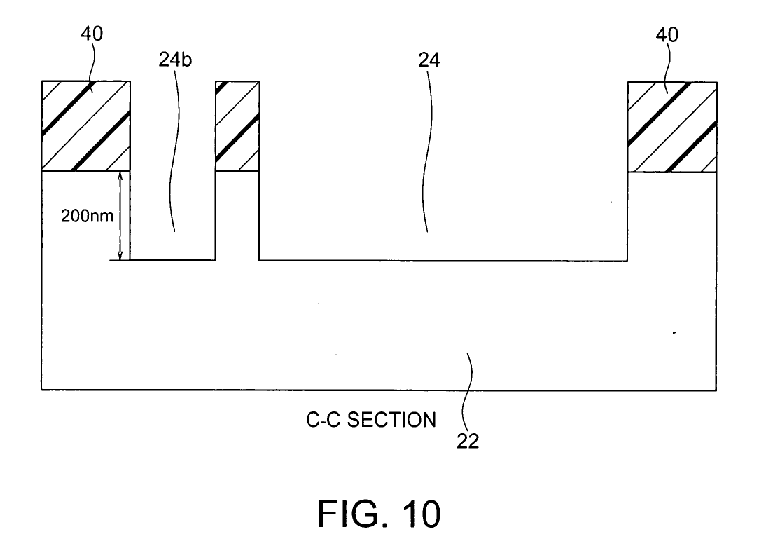

First, the surface of a silicon single crystal substrate 22 is coated with a resist, and exposure and development are conducted. As a result, a resist pattern 40 having an opening in an area where the void should be formed is formed. By using the resist pattern 40 as a mask and conducting reactive ion etching (hereafter referred to as RIE) with plasma, the silicon single crystal substrate 22 is subjected to etch working. As a result, a first void 24 surrounding the element region 25, a second void 24a, and a third void 24b connected to the first void 24 via the second void 24a are formed in the silicon single crystal substrate 22 as shown in FIG. 7. By the way, FIG. 7 is a plan view of the silicon single crystal substrate 22 at this time. FIG. 8 is a sectional view taken along a line A-A shown in FIG. 7. FIG. 9 is a sectional view taken along a line B-B shown in FIG. 7. FIG. 10 is a sectional view taken along a line C-C shown in FIG. 7. As appreciated from FIGS. 7 and 10, the second void 24a has a narrower width than that of the first void 24, and the second void 24a is referred to as necking region as well. Bottoms of the first to third voids 24, 24a and 24b are co-planar. In the present example, the case where the first to third voids 24, 24a and 24b have a depth of 200 nm is shown. By the way, a dummy insulation film may be interposed between the resist pattern 40 and the substrate 22.

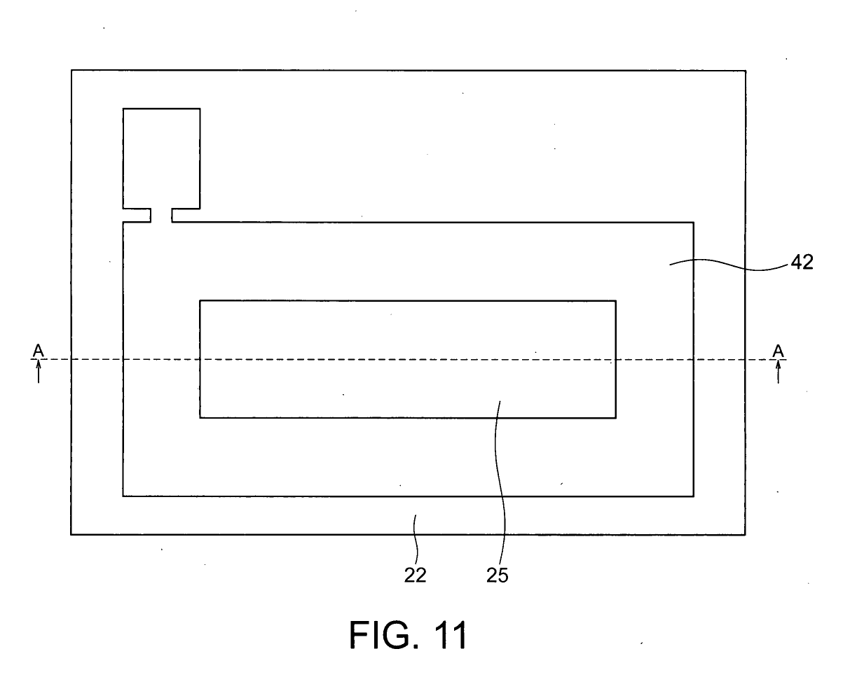

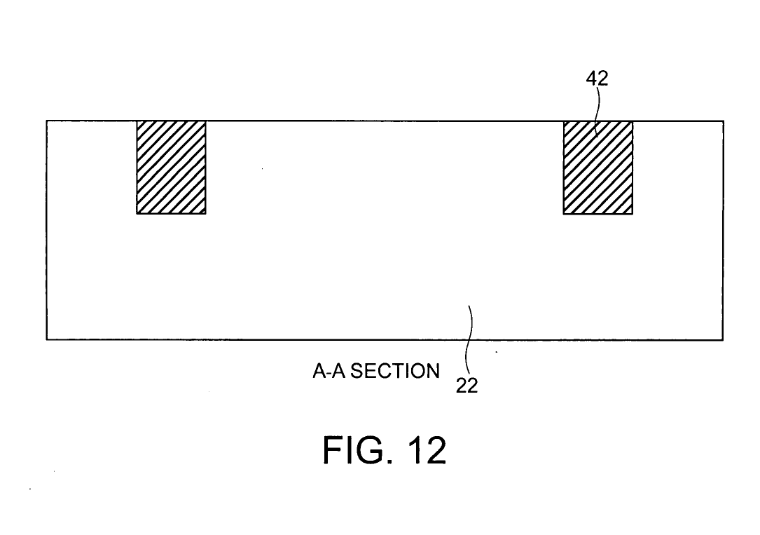

After the resist pattern 40 is peeled off, oxidation processing for rounding corners of the substrate 22 is conducted. An oxide film formed by the oxidation processing is etched and removed by dilute fluoric acid processing. Thereafter, a silicon oxide 42, such as TEOS (tetra ethyl ortho silicate) is buried in the first to third voids 24, 24a and 24b, and then planarization processing is conducted (see FIGS. 11 and 12). FIG. 11 is a plan view of the semiconductor substrate 22 at this time. FIG. 12 is a sectional view taken along a line A-A shown in FIG. 11.

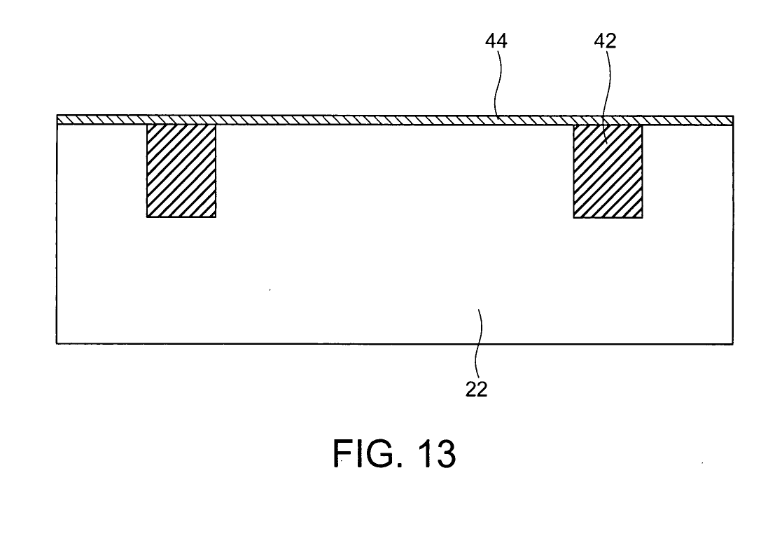

Subsequently, the substrate 22 is subjected to pre-processing. Thereafter, an insulation film 44, such as a HfO₂ film, of approximately 3 nm is deposited on the surface of the substrate 22 by CVD film forming according to the bubbling method using a liquid source such as Hf[N(CH₃)₂]₄ (tetrakis (dimethylamino) hafnium). Heat treatment after deposition (post deposition anneal which is hereafter referred to as PDA) is conducted (see FIG. 13). By the way, FIG. 13 is a sectional view taken along a line A-A when the insulation film 44 is formed on the semiconductor substrate shown in FIG. 11.

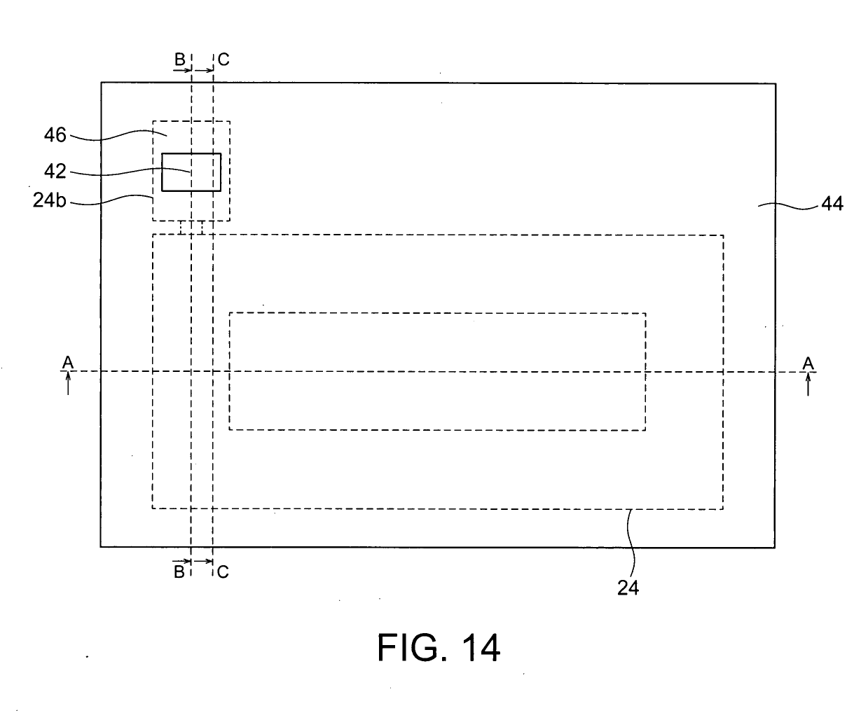

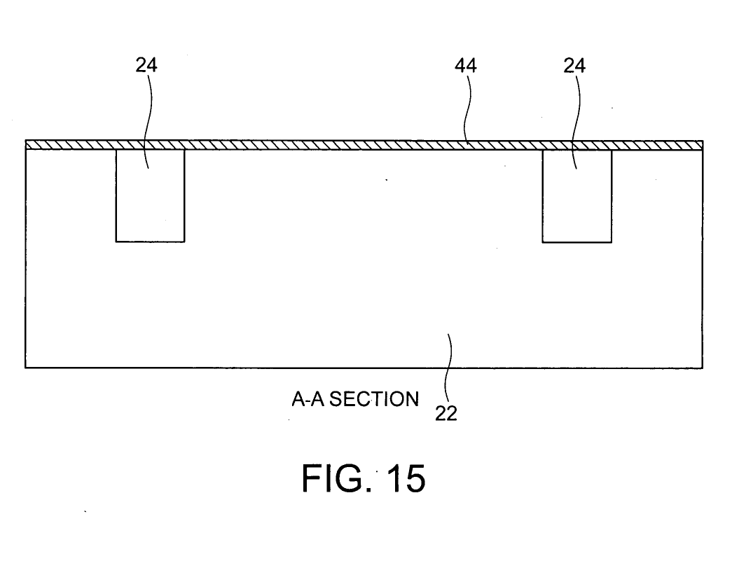

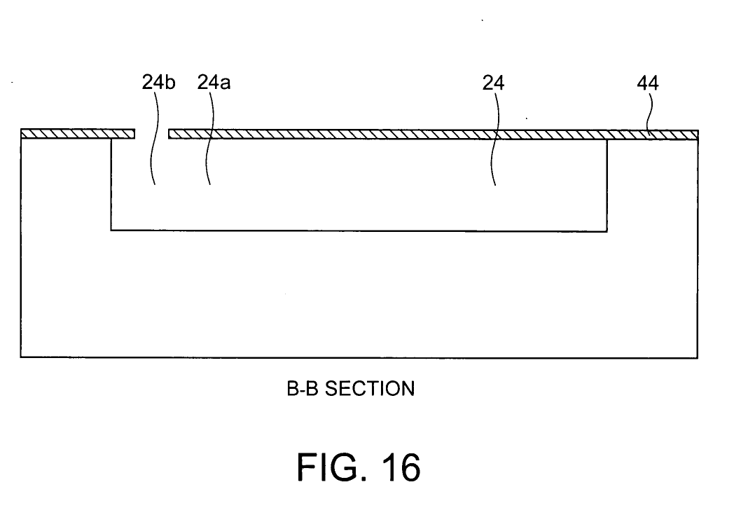

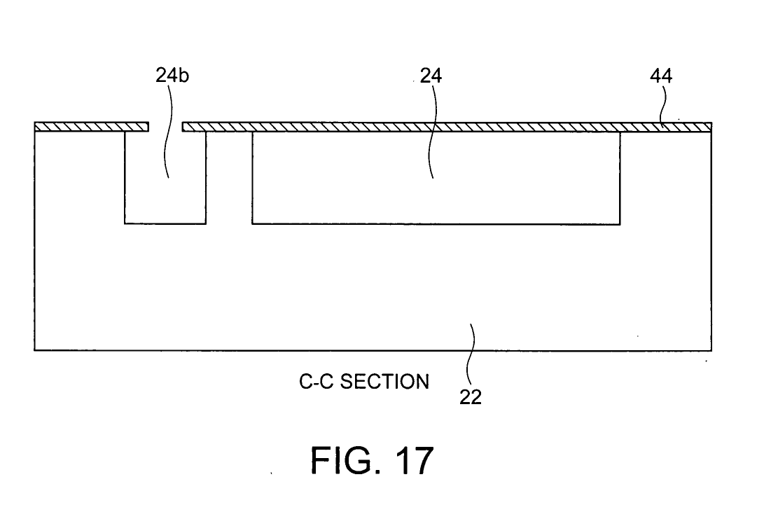

Subsequently, as shown in FIG. 14, an opening 46 having the silicon oxide 42 exposed at its bottom is formed in the insulation film 44 on the third void 24b by using the lithography technique. Thereafter, the silicon oxide buried in the voids 24, 24a and 24b is etched and removed by using dilute fluoric acid (see FIGS. 15, 16 and 17). FIG. 15 is a sectional view obtained by cutting the semiconductor substrate after the etching removal along a cutting line A-A shown in FIG. 14. FIG. 16 is a sectional view obtained by cutting the semiconductor substrate after the etching removal along a line B-B shown in FIG. 14. FIG. 17 is a sectional view obtained by cutting the semiconductor substrate after the etching removal along a line C-C shown in FIG. 14. As appreciated from FIGS. 15 to 17, the silicon substrate 22 and the insulation film 44 formed of HfO₂ are hardly etched by dilute fluoric acid at the time of the etching. In general, the high permittivity film after the heat treatment is higher in etching resistance against dilute fluoric acid than the silicon oxide. Therefore, it is possible to etch and remove the silicon oxide with high selectivity with respect to HfO₂ after PDA as in the present example.

A process for closing the void 24a called necking region will now be described. Polysilicon is deposited at approximately 600° by using silane gas. Silane gas enters the voids 24b, 24a and 24 from the opening 46 shown in FIG. 14, and polysilicon is deposited in the voids 24, 24a and 24b. At this time, the width of the necking region 24a is narrower than the width of the void 24 surrounding the element region. Therefore, the necking region 24a is closed by deposition of polysilicon before the void 24 is completely covered by polysilicon. After the necking region 24a is closed, the deposition of polysilicon in the void 24 surrounding the element region is suppressed.

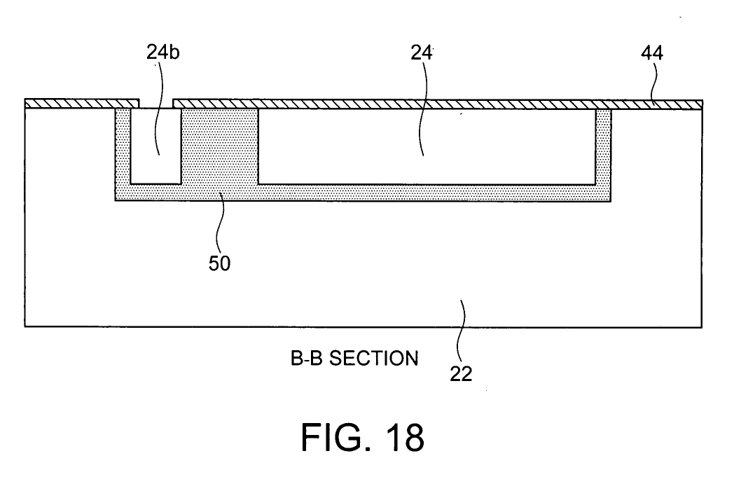

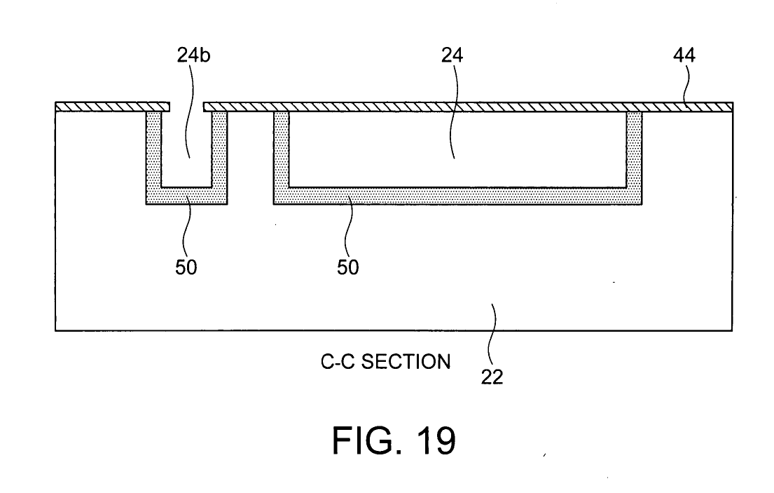

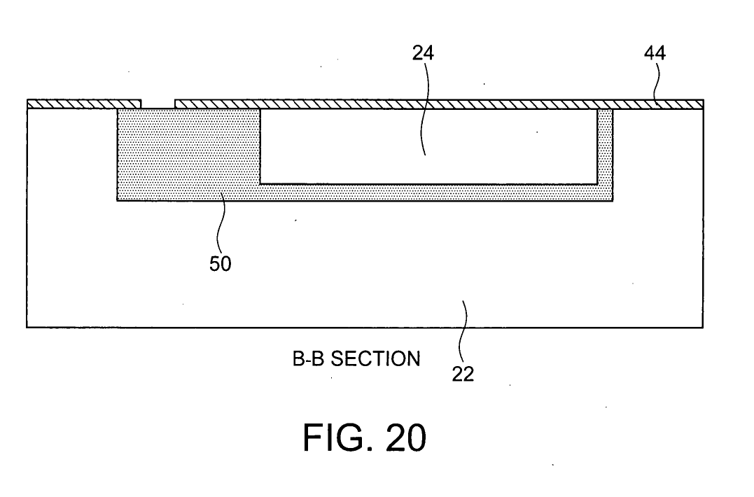

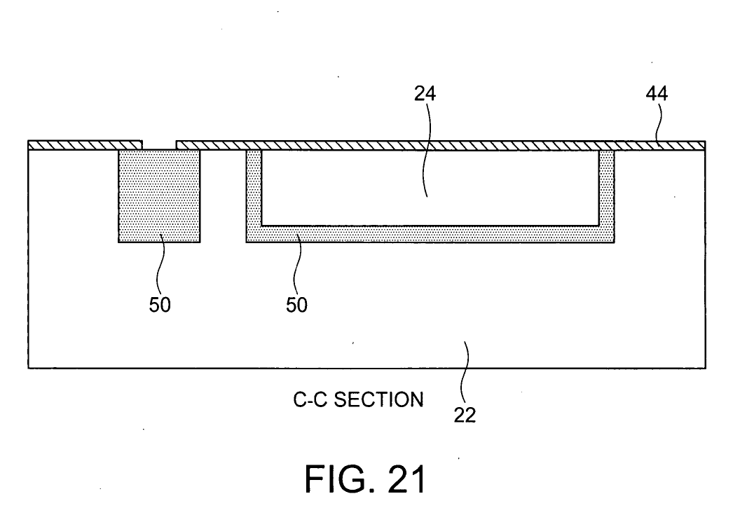

As for the method for closing the necking region 24a, it is also possible to use epitaxial growth of silicon using silane or disilane, thermal oxidation of the silicon substrate, or deposition of amorphous silicon or the insulation film besides the deposition of polysilicon. A silicon film 50 formed on bottom faces and side faces of the voids 24 and 24b by epitaxial growth when the necking region 24a is not yet blocked is shown in FIGS. 18 and 19. FIG. 18 is a sectional view taken along a line B-B shown in FIG. 14. FIG. 19 is a sectional view taken along a line C-C shown in FIG. 14. In addition, the B-B section and the C-C section of the semiconductor substrate 22 at the time when epitaxial growth is executed and the necking region 24a is blocked are shown in FIGS. 20 and 21, respectively.

It is not always necessary that the necking region 24a is co-planar. If the necking region 24a is co-planar as in the present example, however, only one mask is needed and the cost required for the process is low.

In the present example, the example of providing one opening 46 per element region 25 has been described. Alternatively, a void in which one opening 46 surrounds a plurality of element regions may be formed. Or a plurality of openings may be provided per element region.

When sealing the opening, the void may be filled with inert gas such as He, Ne or Ar, or a gas such as nitrogen.

In the present example, the process for etching and removing TEOS in the element isolation region is conducted in the pre-process. Alternatively, this process may be conducted in the post-process after wiring formation. In this case, the highest temperature which can be applied when sealing the necking region is limited. It is also possible to form a contact which reaches up to the void in the post-process, fill the void with the coolant, circulate the coolant by using a micro-machine developed in recent years, and thereby efficiently remove heat generated in the element and bring the element into stable operation.

### THIRD EXAMPLE

A third example of the present invention will now be described. First, a region which should become the element isolation region in the Si single crystal substrate is etched and removed by using RIE. Subsequently, a germanium oxide is buried in the etched and removed region, and the surface is planarized by CMP (chemical mechanical polishing) to form an STI (shallow trench isolation) region.

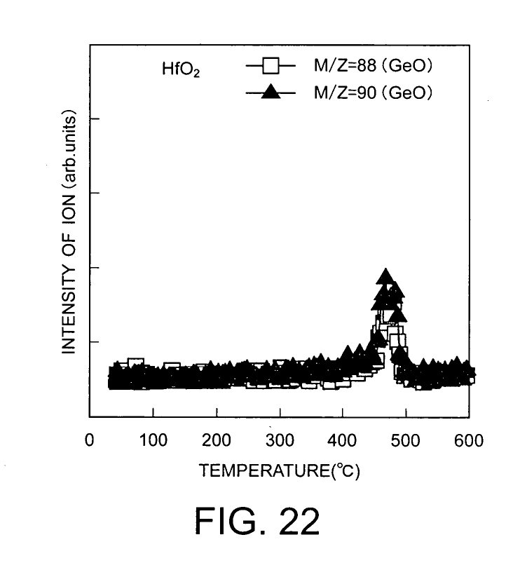

Subsequently, an insulation film of HfO₂ having a thickness of 3 nm is formed by sputtering at room temperature. Subsequently, a heat treatment process is executed in an atmosphere of nitrogen at 600° C. The germanium oxide in the STI region is diffused to an insulation film made of HfO₂ to form a void in the STI region. The present inventors have found that degassing of GeO(g) in an HfO₂/GeO₂ stacked structure begins from approximately 420° C., and degassing is conducted beyond HfO₂ so as to reach the peak at approximately 480° C. as shown in FIG. 22. Furthermore, it is reported that degassing of GeO occurs at approximately 420° C. in a situation where the GeO₂ film is not formed (see, for example, K. Prabarahakan, et al., Appl. Phys. Lett. 76 2244 (2000)). Therefore, it is desirable to conduct deposition of the insulation film at 420° C. or less as in the present example. If the insulation film is deposited at 420° C. or more, then degassing of GeO begins at the time of pre-annealing before deposition, and the insulation film surface after the deposition takes a concave shape on the region corresponding to the element isolation region. This is the reason why it is desirable to conduct deposition of the insulation film at 420° C. or less. Furthermore, it is desirable that the heat treatment temperature after the deposition of the insulation film is 420° C. or more for the above-described reason.

### FOURTH EXAMPLE

A fourth example of the present invention will now be described. First, a region which should become the element isolation region in the Si single crystal substrate is etched and removed by using RIE. Subsequently, germanium is buried in the etched and removed region, and the surface is planarized by CMP to form an STI region.

Subsequently, an insulation film of HfO₂ having a thickness of 3 nm is formed by sputtering at room temperature. Subsequently, a heat treatment process is executed in the vacuum at 600° C. to form a void in the germanium region in the STI region.

### FIFTH EXAMPLE

A fifth example of the present invention will now be described. First, a dummy SiO₂ film is deposited on a Ge substrate. A resist pattern having an opening on an area where a void should be formed is formed on the dummy SiO₂ film. Ion implantation of Ge into the area where the void should be formed is conducted by using the resist pattern as a mask. As a result, Ge in the region is made amorphous.

Subsequently, the dummy SiO₂ film is peeled off by dilute fluoric acid processing. Thereafter, a ZrO₂ film having a thickness of 10 nm is formed by using the CVD method. Ge in an area where the void should be formed is diffused to the ZrO₂ film by nitrogen heat treatment at 500° C. to form a void in the area where the void should be formed.

Subsequently, a polysilicon film is formed in gas containing silane at 600° C. Wiring opposed to the void via an insulation film is formed by patterning the polysilicon film.

As for the process for forming crystal defects by damaging the substrate when forming an area where the void should be formed, an anisotropic etching process using plasma, the ordinary ion implantation process, or a process of plasma nitriding may also be used.

### SIXTH EXAMPLE

A sixth example of the present invention will now be described. First, a ZrO₂ film having a thickness of 10 nm is formed on a Si substrate having a shallow buried element isolation region (STI region) formed therein, by sputter deposition, and heat treatment is conducted at 500° C. Thereafter, a partial region of the ZrO₂ film is etched by anisotropic etching using plasma to form an opening through the ZrO₂ film. This opening is connected to the STI region via a necking region. Subsequently, the insulation film in the STI region linked to the opening is etched and removed by dilute fluoric acid to form a void in the STI region. The STI is typically formed of SiO₂. Furthermore, etching resistance of the high permittivity film ZrO₂ subjected to the heat treatment against dilute fluoric acid is increased. Therefore, SiO₂ can be selectively etched by dilute fluoric acid.

Epitaxial growth of silicon is conducted by using silane gas at 750° C. to block the necking region. Subsequently, a polysilicon film is formed in the same chamber without exposing it to the atmosphere. Thereafter, an electrode is formed vertically upward of the void via the ZrO₂ film.

It is not always necessary to provide the opening adjacent to the necking region separately in an area other than the necking region. The opening contact may fall directly on the necking region. In addition, if the diameter of the contact is shorter than the thickness of the BOX layer, the contact can be substituted for the necking region.

### SEVENTH EXAMPLE

A seventh example of the present invention will now be described. First, a dummy SiO₂ film is deposited on a Ge substrate. A resist pattern having an opening on an area where a void should be formed is formed on the dummy SiO₂ film. Thereafter, ion implantation of Ge into the area where the void should be formed is conducted by using the resist pattern as a mask. As a result, Ge in the region is made amorphous.

Subsequently, the dummy SiO₂ film is peeled off by dilute fluoric acid processing. Thereafter, a ZrO₂ film having a thickness of 10 nm is formed by using the CVD method. Subsequently, Ge in an area where the void should be formed is diffused to the ZrO₂ film by conducting heat treatment in an atmosphere of nitrogen at 500° C. to form a void in the area where the void should be formed. Thereafter, a polysilicon film is formed on the area where the void is formed via the ZrO₂ film in gas containing silane at 600° C. A detector opposed to the void via an insulation film is formed by patterning the polysilicon film. As for the process for damaging the substrate when forming an area where the void should be formed, an anisotropic etching process using plasma, the ordinary ion implantation process, or a process of plasma nitriding may also be used.

### EIGHTH EXAMPLE

An eighth example of the present invention will now be described. First, a ZrO₂ film having a thickness of 10 nm is deposited on a Si substrate having STI formed therein, by sputter film formation, and heat treatment is conducted at 500° C. A partial region of the ZrO₂ film is etched by anisotropic etching using plasma to form an opening through the ZrO₂ film. This opening is connected to the STI region via a necking region.

Subsequently, the insulation film in the STI region linked to the opening is etched and removed by dilute fluoric acid to form a void. Epitaxial growth of silicon is conducted by using silane gas at 750° C. to block the necking region. Subsequently, a polysilicon film is formed in the same chamber without exposing it to the atmosphere. A detector is formed vertically upward of the void via the ZrO₂ film by patterning the polysilicon film.

### NINTH EXAMPLE

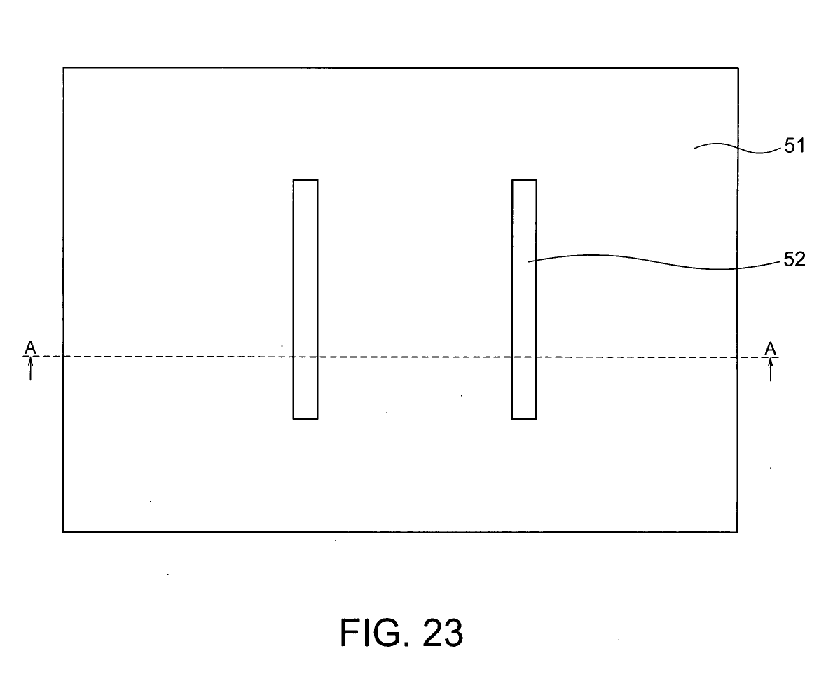

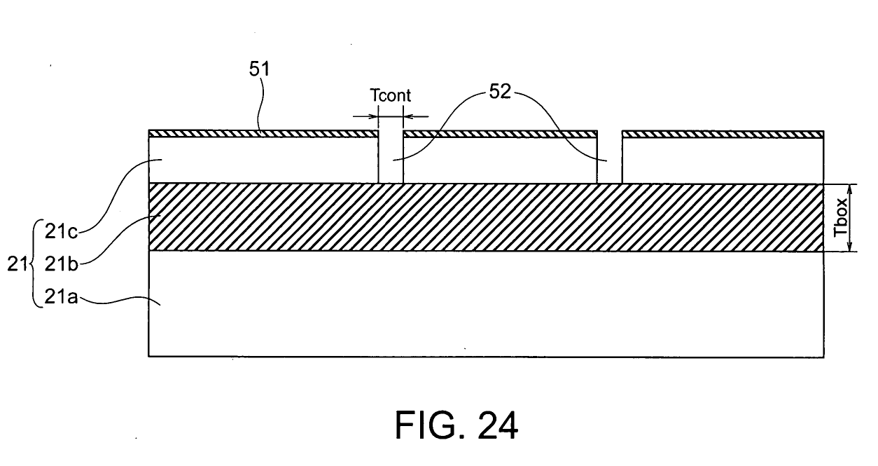

A ninth example of the present invention will now be described with reference to FIGS. 23 to 26. First, an insulation film 51 having a low etching selection ratio for a buried oxide film layer 21 (hereafter referred to also as BOX (buried oxide) layer 21) having a film thickness Tbox in an SOI substrate 21 is formed on an SOI layer 21c. Subsequently, the insulation film 51 and the SOI layer are etched by using the lithography technique to form an opening 52 having an opening diameter Tcont and reaching the BOX layer 21b through the SOI layer 21c (see FIGS. 23 and 24). FIG. 23 is a plan view of the SOI substrate 21 obtained when the opening 52 is formed. FIG. 24 is a sectional view obtained when the substrate is cut along a cutting line A-A shown in FIG. 23.

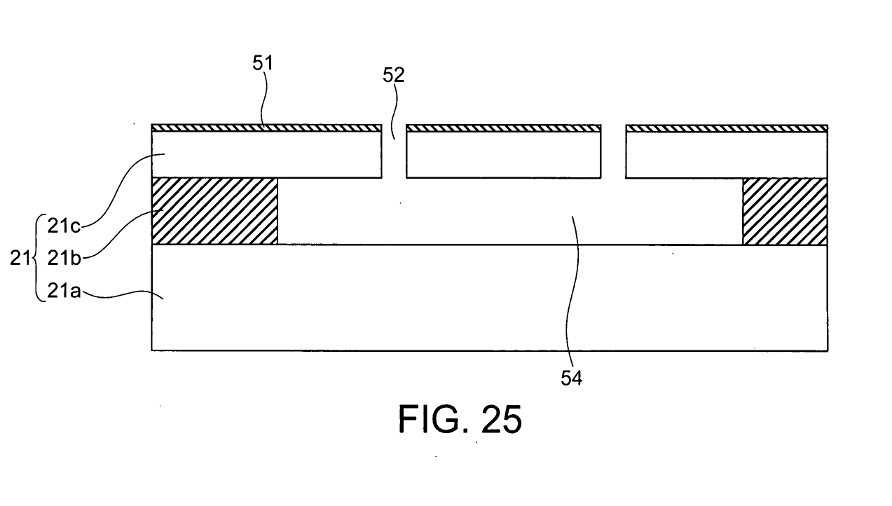

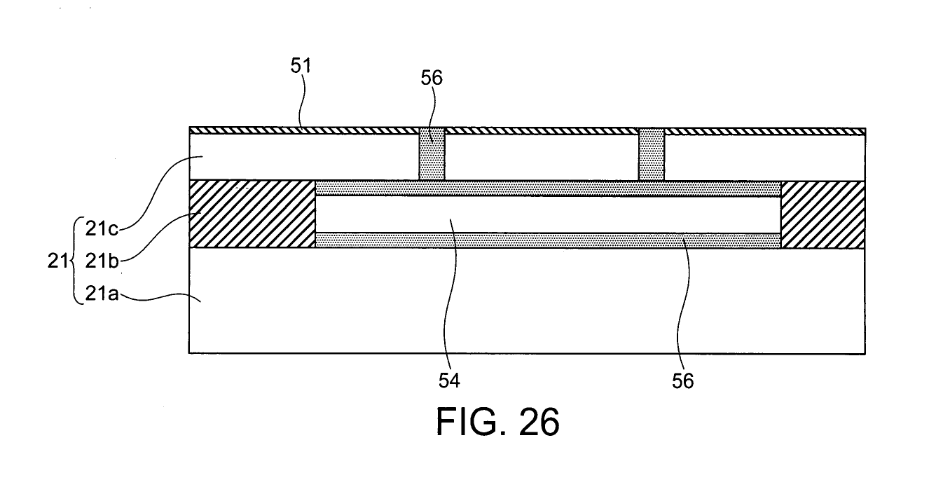

Therefore, a part of the BOX layer 21b is etched and removed by feeding and exhausting a dilute fluoric acid solution from the opening 52 to form a void 54 in the BOX layer 21b (see FIG. 25). Subsequently, the opening 52 is blocked to form a silicon region on the void 54, i.e., SON (silicon (or semiconductor) on nothing) by epitaxial growth of silicon with the substrate 21 serving as the seed (see FIG. 26). At this time, an epitaxial layer 56 is formed in the top face and bottom face of the void 54 and in the opening 52. Thereafter, a device is suitably formed on the SON by using the ordinary method.

In the case where the necking region (the opening 52 in the present example) is blocked by epitaxial growth of silicon as described above, it is desirable that Tbox>Tcont. The same is true of the case where the necking region (the opening 52) is blocked by oxidation of silicon and deposition of the insulation film.

### TENTH EXAMPLE

A tenth example of the present invention will now be described. A film of Ti (titanium) having a thickness of 3 nm is formed on a partial region of an SOI substrate. For example, a resist pattern having an opening in the region is formed on the SOI substrate. Thereafter, Ti is evaporated, and a film of Ti is formed in the region by using the lift-off method.

If the thickness of the SOI layer is thin and energy at the time of evaporation is large, then an interface layer is formed at an interface between Ti and the substrate immediately after the evaporation, and a part of a BOX layer is consumed. At this time, the BOX layer under the Ti film forming region beyond the SOI layer is converted to a void by Ti evaporation using a low energy electron beam and heat treatment after the evaporation in order to reduce the evaporation damage on the substrate and promote the consumption of the BOX layer.

Thereafter, Ti and the interface layer are peeled off. Suitably, a device is formed on the SON by using the ordinary method. By the way, since a Ti oxide formed by heat treatment after the evaporation is a high permittivity film, it can be utilized intact in principle as an insulation film of the device such as a gate insulation film of an FET without peeling as described above.

### ELEVENTH EXAMPLE

An eleventh example of the present invention will now be described with reference to FIG. 3. According to the present example, the semiconductor device in the second example shown in FIG. 3 is formed as far as the wiring 28, and then a contact region (not illustrated) reaching a void 24 in a substrate 22 is formed. Heat generated in an element 23 created on the substrate via the contact region is exhausted by convection of air. As a result, the substrate temperature rise is reduced and stable operation of the element is implemented. By the way, it is also possible to implement a water cooling structure which is more effective as compared with air cooling by filling the contact region and the void 24 in the substrate 22 with a coolant such as water. It is possible, in principle, to implement effective heat radiation by incorporating the micro-machine developed in recent years into the element. For example, it is anticipated that the coolant will be exhausted by convection periodically and effectively without staying in the void, by forming the contact diameter in two places or more, creating valve structures in respective contact regions so as to make valve directions opposite to each other, and giving periodic water flow vibration. As for the valves, valves having only one direction may be used. In this case, an inflow or outflow region having no valves should be formed in one place or more to provide the coolant with vibration.

The above-described insulation film forming method can be suitably changed to an ordinary film forming method such as the sputter method, CVD method, atomic layer CVD method, evaporation method, and coating method.

As for the above-described Si single crystal substrate, a SiGe substrate or Ge substrate with a mixture of Ge, a substrate with a mixture of C, an ordinary semiconductor substrate, an amorphous substrate used in a TFT, a polycrystal substrate, or a compound substrate, one of the substrates having an oxide film buried layer, or an SOI substrate may be used.

As for the insulation film, a high permittivity film or an ordinary insulation film containing SiO₂, SiON, Hf or Zr besides ZrO₂ or HfO₂.

When opening a hole in a semiconductor, it is possible in process to make an aspect ratio, which is a ratio of the depth of the opening to a frontage, equal to several tens, if necessary. As for the trench capacitor, a deep hole having a large aspect ratio is actually dug in order to increase the capacitance.

### TWELFTH EXAMPLE

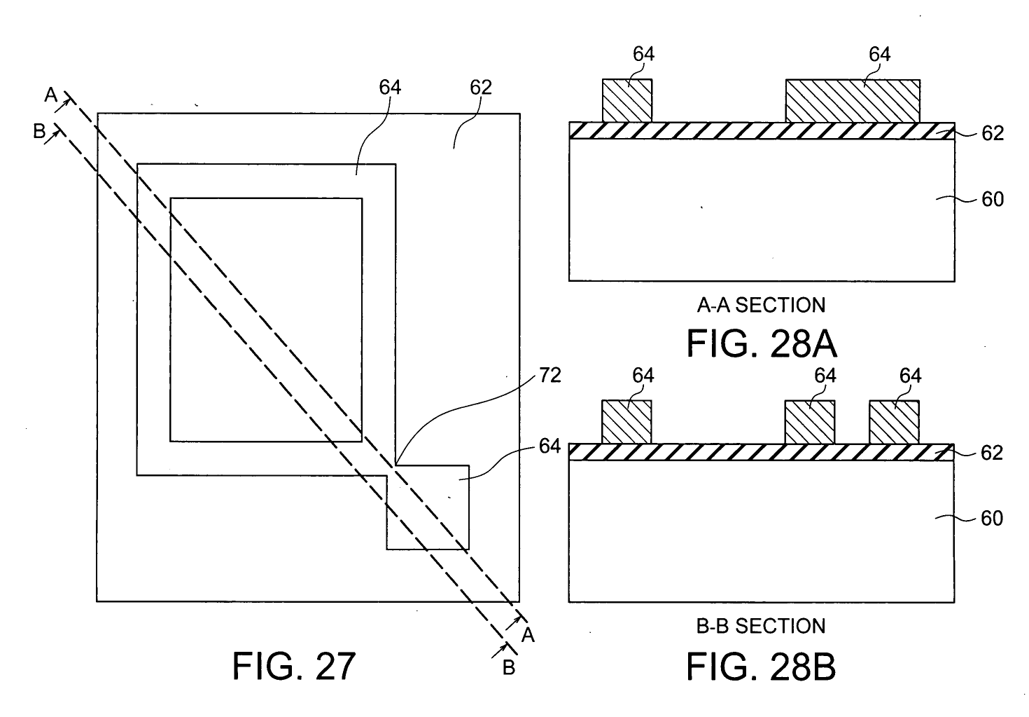

A twelfth example of the present invention will now be described with reference to FIGS. 27 to 36.

First, a ZrO₂ film 62 having a thickness of approximately 5 nm is formed on a Ge substrate 60 by using the sputter method. An oxygen feeding source film functioning as an oxygen feeding source, such as a Mo film containing oxygen, having a thickness of approximately 200 nm is formed on the ZrO₂ film 62 by electron gun evaporation using a Mo target with a degree of vacuum of 2×10⁻⁶ Pa or more. Thereafter, a Mo film 64 is remained on an area where an element isolation region should be formed, by a lithography process (see FIGS. 27, 28A and 28B).

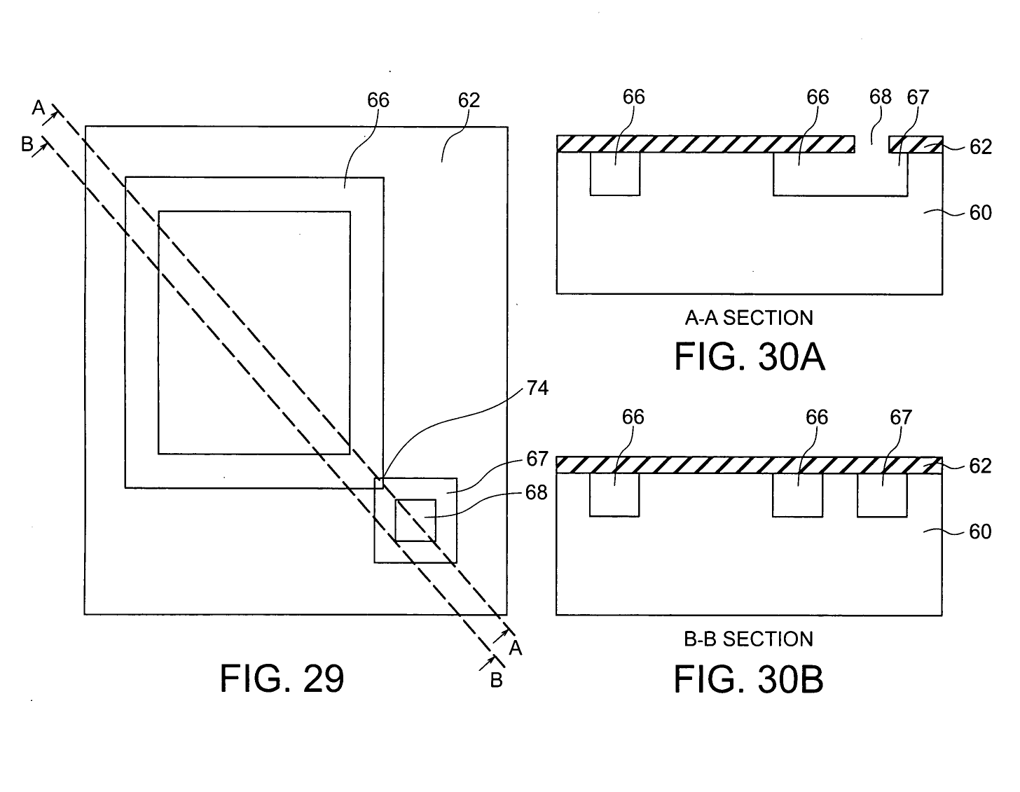

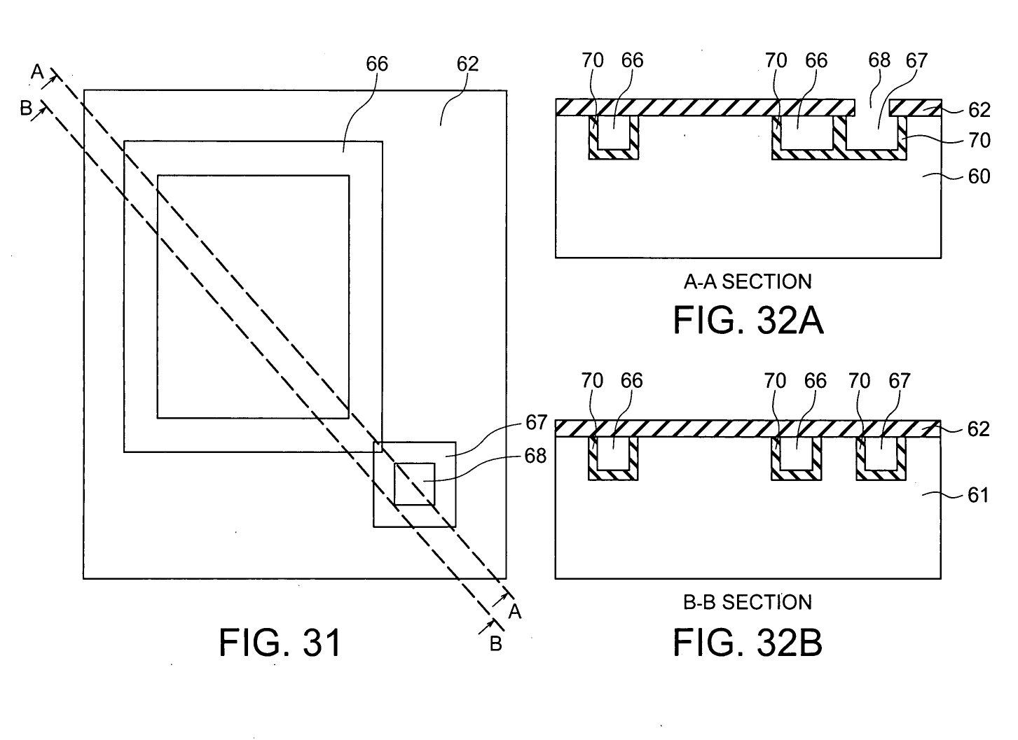

Subsequently, heat treatment is conducted in an atmosphere of nitrogen at 700° C. for 30 minutes. Then, the Mo film 64 is etched and removed selectively with respect to the underlying ZrO₂ film 62 by using hydrogen peroxide water or mixed acid (a mixed solution of fluoric acid and nitric acid). As a result, a first void 66 functioning as an element isolation region and a second void 67 for forming an opening are formed under the ZrO₂ film 62 in areas where the Mo film 64 is removed (areas where element isolation regions should be formed) (see FIGS. 29, 30A and 30B). Formation of voids will be described later. Subsequently, an opening 68 leading to the second void 67 is formed by etching and removing the ZrO₂ film 62 on the second void 67. Thereafter, plasma nitriding gas is made to flow in from the second void 67 via the opening 68. The surface of the Ge substrate 60 where the element isolation region formed of the first void 66 is exposed is subject to plasma nitriding to form a Ge nitride film (protection film) 70 on the surface of the Ge substrate 60 (see FIGS. 31, 32A and 32B). At this time, an oxide film is formed on the surface of Ge depending upon the oxygen partial pressure before nitriding. Finally, a Ge oxide nitride film (GeON) is formed in some cases. However, GeON is known as a stable protection film. In this case as well, GeON has no problem as a protection film of the surface. Furthermore, an insulation film containing Zr known as a stable protection film of Ge, such as a zirconia (ZrO₂) film or a zirconium silicate (ZrSiO) film, may be formed as the protection film 70 instead of the Ge nitride film or the Ge oxide nitride film by using a deposition method such as MOCVD (metal organic chemical vapor deposition). Furthermore, it is possible in principle to substitute a thermally stable insulation film on the Ge substrate. If the quality of the protection film is amorphous at that time, then it is anticipated that diffusion of Ge into the film will be suppressed and deterioration of electrical characteristics will be improved.

If the lithography pattern of the Mo film 64 prescribing the element isolation has a constricted part 72 as shown in FIG. 27, a bottleneck 74 is formed between the first void 66 and the second void 67 as shown in FIG. 31. After formation of the protection film 70, the bottleneck 74 is blocked as shown in FIG. 32A, and the second void 67 is isolated from the element isolation region formed of the first void 66. If the constricted part 72 is not present, then it is necessary to seal the opening after formation of the protection film.

Therefore, the bottleneck 74 is sealed at the time of the process for forming the protection film 70 of the Ge substrate by providing the constricted part 72 as in the present example. As a result, the process can be simplified, and the cost can be reduced.

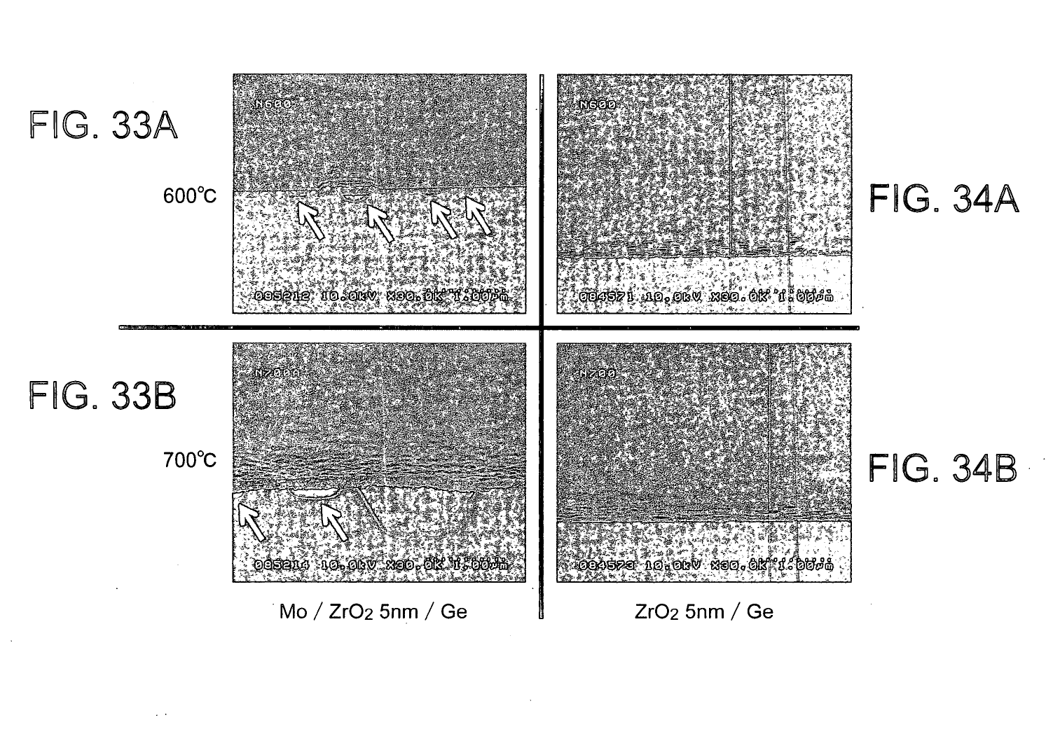

A result of a verification experiment concerning the effect brought about by the Mo film containing oxygen which forms a void in the Ge substrate will now be described. A ZrO₂ film having a thickness of 5 nm is formed on a Ge substrate. A Mo film containing oxygen is formed on the ZrO₂ film. This sample is subjected to heat treatment in an atmosphere of nitrogen at 600° C. and 700° C. for 30 minutes. Sectional photographs of the resultant sample obtained by using an SEM (scanning electron microscope) are shown in FIGS. 33A and 33B. A ZrO₂ film having a thickness of 5 nm is formed on a Ge substrate. A Mo film containing oxygen is not formed on the ZrO₂ film. This sample is subjected to heat treatment in an atmosphere of nitrogen at 600° C. and 700° C. for 30 minutes. Sectional photographs of the resultant sample obtained by using an SEM (scanning electron microscope) are shown in FIGS. 34A and 34B.

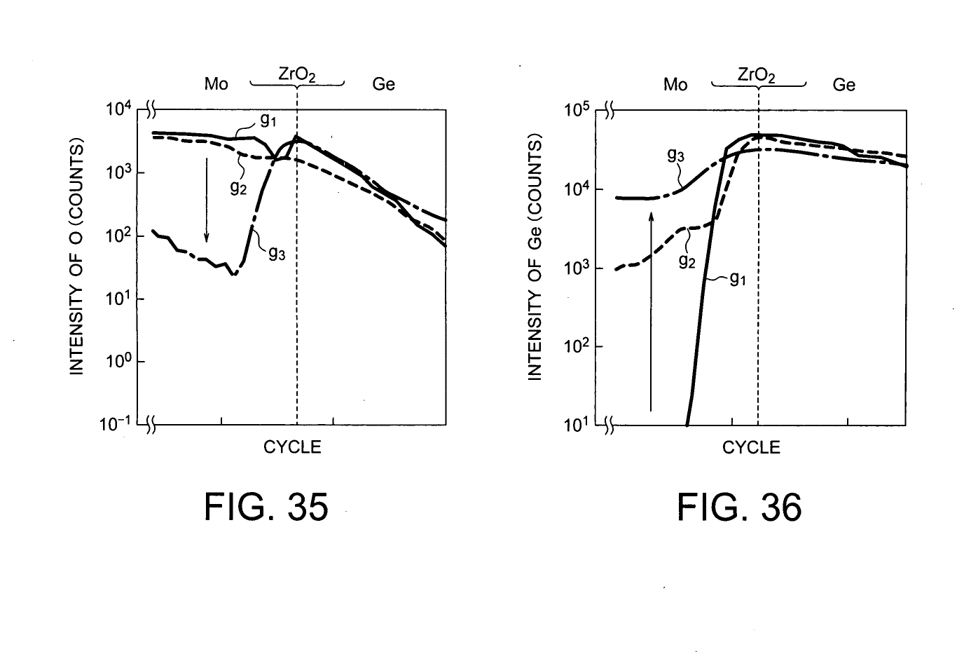

As appreciated from FIGS. 34A and 34B, voids are not formed in the Ge substrate when the Mo film is not present. As appreciated from FIGS. 33A and 33B, voids are formed in the Ge substrate when the Mo film containing oxygen is present on the ZrO₂ film. As the heat treatment temperature becomes higher, void formation is remarkable. In other words, the ZrO₂ film is stable on the Ge substrate. Because of the presence of the Mo film on the ZrO₂ film, however, voids are formed in the Ge substrate. The reason is considered to be that Mo functions as a feeding source of oxygen. This is appreciated from results of an SIMS (secondary ion mass spectroscopy) analysis shown in FIGS. 35 and 36. In FIG. 35, the abscissa indicates a cycle and the ordinate indicates intensity of oxygen. The SIMS measurement is conducted by digging a measurement range and measuring the atom number intensity repeatedly. One measurement is taken as a cycle and indicated on the abscissa. Since the cycle is nearly proportionate to the depth from the surface in the same substance, FIG. 35 shows a profile of oxygen in the depth direction. In FIG. 36, the abscissa indicates a cycle and the ordinate indicates an intensity of germanium. First, it is appreciated that a large quantity of oxygen is present in Mo immediately after deposition of Mo (see graph g₁) from the result of the oxygen profile in the depth direction shown in FIG. 35. The oxygen is decreased somewhat by the heat treatment at 600° C. (see graph g₂). In the case of heat treatment at 700° C., oxygen is further decreased by one digit or more (see graph g₃). On the basis of the Ge profile result in the depth direction shown in FIG. 36, it is appreciated that Ge is not present in Mo immediately after deposition of Mo (see graph g₁), but Ge is diffused into Mo by heat treatment at 600° C. or more (see graph g₂), and Ge is diffused remarkably as the heat treatment temperature becomes higher (see graph g₃).

In a process supposed on the basis of these results, oxygen in the Mo film diffuses as far as the Ge substrate beyond the ZrO₂ film, reacts with the Ge substrate, diffuses into Mo beyond the ZrO₂ film as GeO, diffuses to the outside partially as GeO (gas), and a part of oxygen in the Mo film and the Ge substrate is consumed. In other words, it is considered that oxygen plays an important role in forming void regions in the Ge substrate. The heat treatment temperature suitable in forming voids in the Ge substrate is 600° C. or more.

In general, it is anticipated that metal such as Pt or a high permittivity film such as ZrO₂ will function to activate oxygen. This is considered to promote a phenomenon of oxidizing the Ge substrate and forming GeO. It is considered to be effective in forming void regions in the Ge substrate to form a high permittivity film on the Ge substrate and form metal on the high permittivity film as the oxygen feeding source. In the present example, Mo is used as the oxygen feeding source. However, another metal (such as W) or nonmetal (such as a Ru oxide or ITO (indium tin oxide)) may also be used. It is better to use a metal because oxygen is activated.

According to the embodiments of the present invention, it is possible to provide a semiconductor device capable of reducing the influence upon adjacent elements as far as possible.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a Ge substrate having a void; and
an insulation film containing Ge which covers a top face of the void.

2. The semiconductor device according to claim 1, wherein the void isolates an element region.

3. The semiconductor device according to claim 2, further comprising a field effect transistor which is formed in the element region and which includes a gate insulation film containing a metal,
wherein the insulation film contains the same metal as the gate insulation film besides Ge.

4. The semiconductor device according to claim 1, wherein the insulation film contains a metal oxide serving as a high-k material.

5. The semiconductor device according to claim 4, wherein the insulation film contains ZrO₂ or HfO₂.

6. The semiconductor device according to claim 5, wherein a bonding form of Ge contained in the insulation film is an oxide.

7. A semiconductor device comprising:
a semiconductor substrate having a void;
an insulation film which covers a top face of the void; and
wiring provided on the insulation film above the void.

8. A semiconductor device comprising:
a semiconductor substrate having a void;
an insulation film which covers a top face of the void; and
an infrared detector provided on the insulation film above the void.

9. A semiconductor device comprising:
a semiconductor substrate having a void, a top face of the void being covered by an insulation film,
wherein the void is filled with a coolant for cooling the semiconductor substrate or the coolant passes through the void.

10. A semiconductor device manufacturing method comprising:
forming an insulation film on a Ge substrate; and
forming a void in the Ge substrate under the insulation film.

11. The semiconductor device manufacturing method according to claim 10, wherein the forming of the void in the Ge substrate comprises:
generating a crystal defect in Ge crystal in an area where the void is formed; and
conducting heat treatment.

12. The semiconductor device manufacturing method according to claim 11, wherein the generating of the crystal defect is conducted by using anisotropic etching using plasma, ion implantation, chemical dry etching, or plasma nitriding.

13. The semiconductor device manufacturing method according to claim 10, wherein the forming of the void in the Ge substrate comprises:
forming an oxygen feeding source film on the insulation film;
conducting heat treatment; and
removing the oxygen feeding source film.

14. The semiconductor device manufacturing method according to claim 13, wherein the insulation film contains a metal oxide serving as a high-k material.

15. The semiconductor device manufacturing method according to claim 14, wherein the insulation film contains ZrO₂ or HfO₂.

16. The semiconductor device manufacturing method according to claim 13, wherein the oxygen feeding source film comprises a metal containing oxygen.

17. The semiconductor device manufacturing method according to claim 16, wherein the heat treatment is conducted in an atmosphere of nitrogen at 700° C. or more.

18. A semiconductor device manufacturing method comprising:
etching a surface of a semiconductor substrate, and forming a first void, a second void which is connected to the first void and which is narrower in width than the first void, and a third void connected to the second void;
burying a first insulation film in the first to third voids;
forming a second insulation film which is lower in etching rate than the first insulation film so as to cover a face of the semiconductor substrate in which the first to third voids are formed;
forming an opening which leads to the first insulation film buried in the third void by etching and removing at least a part of the second insulation film on the third void; and
removing the first insulation film buried in the first to third voids by conducting etching via the opening.

19. The semiconductor device manufacturing method according to claim 18, comprising removing the first insulation film and then blocking the second void.

20. A semiconductor device manufacturing method comprising:
forming an insulation film on a surface of an SOI substrate;
etching the insulation film and an SOI layer of the SOI substrate and thereby forming an opening leading to a buried oxide film of the SOI substrate; and
etching and removing a partial region of the buried oxide film via the opening and thereby forming a void.
